(19) United States
(12) Patent Application Publication
(10) Pub. No.: US 2004/0192033 A1
(43) Pub. Date: Sep. 30, 2004

(54) Semiconductor device, method of manufacturing the same, circuit board, and electronic instrument

(76) Inventor: Kazumi Hara, Suwa-shi (JP)

Correspondence Address: HARNESS, DICKEY & PIERCE, P.L.C., P.O. BOX 828, BLOOMFIELD HILLS, MI, 48303, US

(21) Appl. No.: 10/757,372

(22) Filed: Jan. 14, 2004

(30) Foreign Application Priority Data
Jan. 15, 2003 (JP) 2003-007280

(51) Int. Cl. H01L 21/301

(52) U.S. Cl. 438/667; 438/692; 438/460

(57) ABSTRACT

A depression is formed in a semiconductor substrate, in which an integrated circuit is formed, from a first surface of the semiconductor substrate. A conductive section is formed in the depression. The conductive section is caused to project from a second surface of the semiconductor substrate opposite to the first surface. The conductive section is ground or polished until the fresh surface is exposed.

Japanese Patent Application No. 2003-7280, filed on Jan. 15, 2003, is hereby incorporated by reference in its entirety.

### BACKGROUND OF THE INVENTION

The present invention relates to a semiconductor device, a method of manufacturing the same, a circuit board, and an electronic instrument.

A semiconductor device in three-dimensional mounting form has been developed. It is known in the art that a penetrating electrode is formed in a semiconductor chip in order to enable three-dimensional mounting. The penetrating electrode is formed to project from the semiconductor chip. In a conventional method of forming the penetrating electrode, it is difficult to form the projecting section of the penetrating electrode so as to be excelling in electrical connection characteristics.

### BRIEF SUMMARY OF THE INVENTION

According to one aspect of the present invention, there is provided a method of manufacturing a semiconductor device comprising:

(a) forming a depression in a semiconductor substrate from a first surface of the semiconductor substrate, an integrated circuit being formed in the semiconductor substrate;

(b) forming a conductive section in the depression;

(c) causing the conductive section to project from a second surface of the semiconductor substrate, the second surface being opposite to the first surface; and

(d) grinding or polishing the conductive section until a fresh surface of the conductive section is exposed.

According to another aspect of the present invention, there is provided a semiconductor device manufactured by the above-described method.

According to a further aspect of the present invention, there is provided a circuit board on which the above-described semiconductor device is mounted.

According to still another aspect of the present invention, there is provided an electronic instrument comprising the above-described semiconductor device.

### BRIEF DESCRIPTION OF THE SEVERAL VIEWS OF THE DRAWING

FIGS. 1A to 1D are views illustrating a method of manufacturing a semiconductor device according to an embodiment of the present invention.

FIGS. 2A to 2D are views illustrating a method of manufacturing a semiconductor device according to an embodiment of the present invention.

FIGS. 3A to 3C are views illustrating a method of manufacturing a semiconductor device according to an embodiment of the present invention.

FIG. 4 is a view illustrating a method of manufacturing a semiconductor device according to an embodiment of the present invention.

FIG. 5 is a view illustrating a method of manufacturing a semiconductor device according to an embodiment of the present invention.

FIG. 6 is a view illustrating a method of manufacturing a semiconductor device according to an embodiment of the present invention.

FIG. 7 is a view illustrating a semiconductor device according to an embodiment of the present invention.

FIG. 8 is a view showing a circuit board according to an embodiment of the present invention.

FIG. 9 is a view showing an electronic instrument according to an embodiment of the present invention.

FIG. 10 is a view showing another electronic instrument according to an embodiment of the present invention.

### DETAILED DESCRIPTION OF THE EMBODIMENT

An objective of embodiments of the present invention is to form a high quality penetrating electrode.

(1) According to one embodiment of the present invention, there is provided a method of manufacturing a semiconductor device comprising:

(a) forming a depression in a semiconductor substrate from a first surface of the semiconductor substrate, an integrated circuit being formed in the semiconductor substrate;

(b) forming a conductive section in the depression;

(c) causing the conductive section to project from a second surface of the semiconductor substrate, the second surface being opposite to the first surface; and

(d) grinding or polishing the conductive section until a fresh surface of the conductive section is exposed. According to this method of manufacturing a semiconductor device, since the fresh surface of the conductive section is exposed, a penetrating electrode excelling in electrical connection characteristics can be formed.

(2) The method of manufacturing a semiconductor device may further comprise:

forming an insulating layer on a bottom surface and an inner wall surface of the depression after the step (a) and before the step (b),

wherein the conductive section may be formed inside the insulating layer in the step (b).

(3) In the method of manufacturing a semiconductor device, the conductive section may be caused to project in the step (c) in a state in which the conductive section is covered with the insulating layer, and

the insulating layer and the conductive section may be ground or polished in the step (d).

(4) In the method of manufacturing a semiconductor device, the conductive section may be caused to project from the second surface of the semiconductor substrate in the step (c) by etching the second surface using an etchant having properties which cause the amount of etching to the semiconductor substrate to be greater than the amount of etching to the insulating layer.

(5) In the method of manufacturing a semiconductor device, the semiconductor substrate may be a semiconductor wafer in which a plurality of the integrated circuits are formed, and the depression may be formed corresponding to each of the integrated circuits, and

the method may further comprise cutting the semiconductor substrate.

(6) The method of manufacturing a semiconductor device may further comprise:

stacking a plurality of the semiconductor substrates which has been subjected to the steps (a) to (d), and electrically connecting the semiconductor substrates through a plurality of the conductive sections.

(7) According to another embodiment of the present invention, there is provided a semiconductor device manufactured by any one of the above-described methods.

(8) According to a further embodiment of the present invention, there is provided a circuit board on which the above-described semiconductor device is mounted.

(9) According to still another embodiment of the present invention, there is provided an electronic instrument comprising the above-described semiconductor device.

The embodiments of the present invention are described below with reference to the drawings.

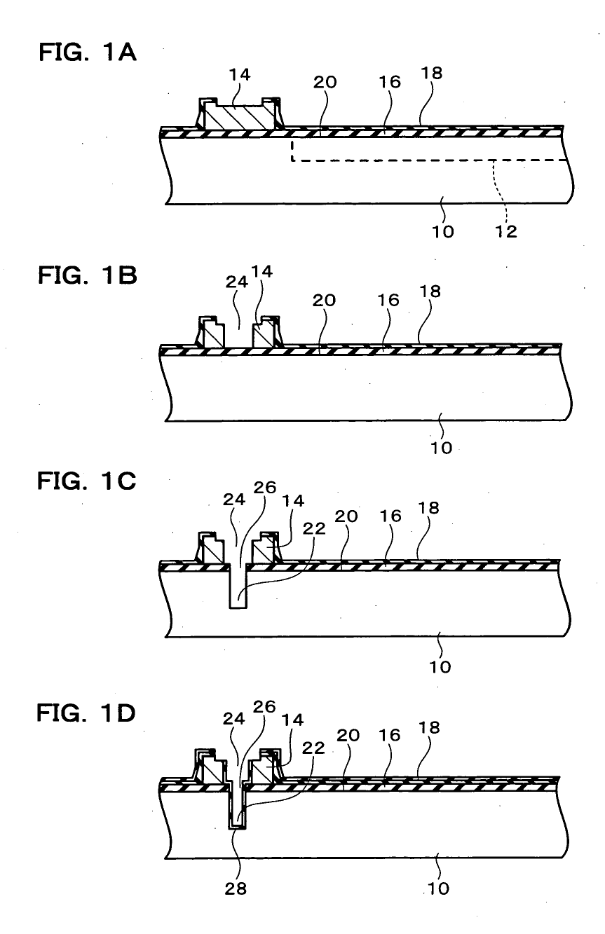

FIGS. 1A to 3C are views illustrating a method of manufacturing a semiconductor device according to an embodiment to which the present invention is applied. In the present embodiment, a semiconductor substrate 10 is used. The semiconductor substrate 10 shown in FIG. 1A is a semiconductor wafer. However, the semiconductor substrate 10 may be a semiconductor chip. At least one integrated circuit 12 (circuit including a transistor or memory, for example) is formed in the semiconductor substrate 10 (a plurality of integrated circuits 12 are formed in a semiconductor wafer, and one integrated circuit 12 is formed in a semiconductor chip). A plurality of electrodes 14 (pads, for example) are formed on the semiconductor substrate 10. The electrode 14 is electrically connected with the integrated circuit 12. The electrode 14 may be formed of aluminum. The shape of the surface of the electrode 14 is not limited, and is generally quadrilateral. In the case where the semiconductor substrate 10 is a semiconductor wafer, at least two (one group of) electrodes 14 are formed in each of the regions which become a plurality of semiconductor chips.

One or more layers of passivation films 16 and 18 are formed on the semiconductor substrate 10. The passivation films 16 and 18 may be formed of SiO₂, SiN, or a polyimide resin, for example. In the example shown in FIG. 1A, the electrode 14 and an interconnect (not shown) which connects the electrode 14 with the integrated circuit 12 are formed on the passivation film 16. The passivation film 18 is formed to avoid at least a part of the surface of the electrode 14. The passivation film 18 may be formed to cover the surface of the electrode 14, and a part of the electrode 14 may be exposed by etching a part of the passivation film 18. The passivation film 18 may be etched by either dry etching or wet etching. The surface of the electrode 14 may be etched when etching the passivation film 18.

In the present embodiment, a depression 22 (see FIG. 1C) is formed in the semiconductor substrate 10 from a first surface 20. The first surface 20 is the surface on the side on which the electrode 14 is formed (side on which the integrated circuit 12 is formed). The depression 22 is formed to avoid devices and interconnects of the integrated circuit 12. As shown in FIG. 1B, a through-hole 24 may be formed through the electrode 14. The through-hole 24 may be formed by etching (dry etching or wet etching). The electrode 14 may be etched after forming a resist (not shown) patterned by using a lithographic step. In the case where the passivation film 16 is formed under the electrode 14, a through-hole 26 (see FIG. 1C) is formed through the passivation film 16. In the case where etching of the electrode 14 stops at the passivation film 16, the through-hole 26 may be formed by using an etchant differing from the etchant used to etch the electrode 14. In this case, a resist (not shown) patterned by using a lithographic step may be formed.

As shown in FIG. 1C, the depression 22 is formed in the semiconductor substrate 10 so as to be connected with the through-hole 24 (and the through-hole 26). The through-hole 24 (and the through-hole 26) and the depression 22 may be collectively referred to as a depression. The depression 22 may be formed by etching (dry etching or wet etching). The semiconductor substrate 10 may be etched after forming a resist (not shown) patterned by using a lithographic step. A laser (CO₂ laser or YAG laser, for example) may be used to form the depression 22. A laser may be used to form the through-holes 24 and 26. The depression 22 and the through-holes 24 and 26 may be continuously formed by using one type of etchant or laser. A sand blasting processing may be used to form the depression 22.

As shown in FIG. 1D, an insulating layer 28 may be formed inside the depression 22. The insulating layer 28 may be an oxide film. In the case where the material for the semiconductor substrate 10 is Si, the insulating layer 28 may be formed of either SiO₂ or SiN. The insulating layer 28 is formed on the bottom surface of the depression 22. The insulating layer 28 is also formed on the inner wall surface of the depression 22. The insulating layer 28 is formed so that the depression 22 is not filled with the insulating layer 28. Specifically, a depression is formed by the insulating layer 28. The insulating layer 28 may be formed on the inner wall surface of the through-hole 26 in the passivation film 16. The insulating layer 28 may be formed on the passivation film 18.

The insulating layer 28 may be formed on the inner wall surface of the through-hole 24 in the electrode 14. The insulating layer 28 is formed to avoid a part (upper surface, for example) of the electrode 14. The insulating layer 28 may be formed to cover the entire surface of the electrode 14, and a part of the electrode 14 may be exposed by etching (dry etching or wet etching) a part of the insulating layer 28. The insulating layer 28 may be etched after forming a resist (not shown) patterned by using a lithographic step.

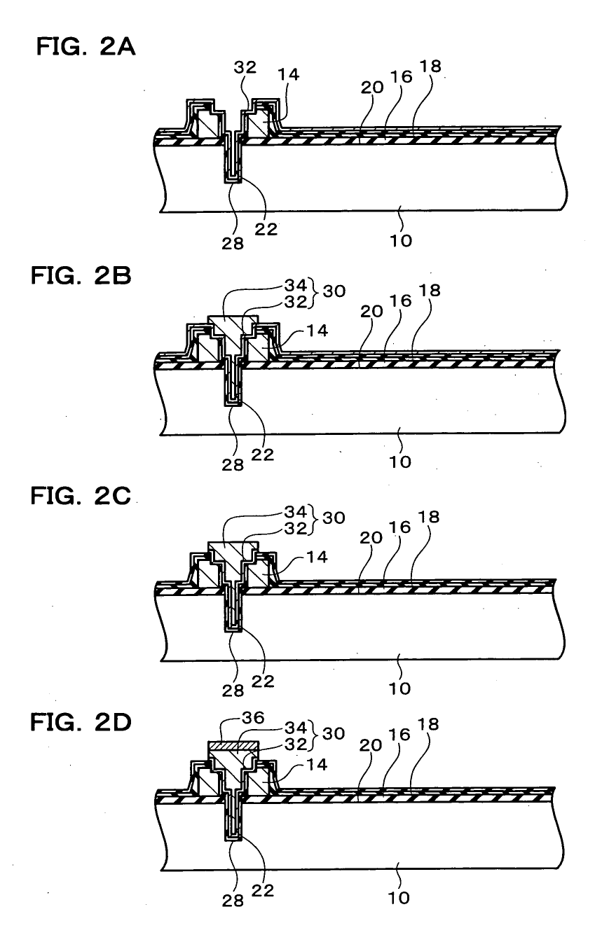

A conductive section 30 (see FIG. 2B) is provided in the depression 22 (inner side of the insulating layer 28, for example). The conductive section 30 may be formed of Cu, W, or the like. After forming an outer layer section 32 of the conductive section 30 as shown in FIG. 2A, a center section 34 of the conductive section 30 may be formed. The center section 34 may be formed of Cu, W, or doped polysilicon (low-temperature polysilicon, for example). The outer layer section 32 may include at least a barrier layer. The barrier layer prevents the material for the center section 34 or a seed layer described below from diffusing into the semiconductor substrate 10 (Si, for example). The barrier layer may be formed of a material differing from the material for the center section 34 (TiW or TiN, for example). In the case of forming the center section 34 by electroplating, the outer layer section 32 may include a seed layer. The seed layer is formed after forming the barrier layer. The seed layer is formed by using the same material as the material for the center section 34 (Cu, for example). The conductive section 30 (at least the center section 34) may be formed by electroless plating or using an ink-jet method.

As shown in FIG. 2B, in the case where the outer layer section 32 is also formed on the passivation film 18, the outer layer section 32 is etched in the area formed on the passivation film 18, as shown in FIG. 2C. The conductive section 30 can be formed by forming the center section 34 after forming the outer layer section 32. A part of the conductive section 30 is located in the depression 22 in the semiconductor substrate 10. Since the insulating layer 28 is present between the inner wall surface of the depression 22 and the conductive section 30, the inner wall surface of the depression 22 is not electrically connected with the conductive section 30. The conductive section 30 is electrically connected with the electrode 14. The conductive section 30 may be in contact with the section of the electrode 14 exposed from the insulating layer 28, for example. A part of the conductive section 30 may be located on the passivation film 18. The conductive section 30 may be formed only inside the region of the electrode 14. The conductive section 30 may project over at least the depression 22. The conductive section 30 may project from the passivation film 18, for example.

As a modification, the center section 34 may be formed in a state in which the outer layer section 32 remains on the passivation film 18. In this case, since a layer continuous with the center section 34 is also formed on the passivation film 18, this layer is etched.

As shown in FIG. 2D, a filler metal 36 may be formed on the conductive section 30. The filler metal 36 is formed of solder, for example. The filler metal 36 may be formed of either soft solder or hard solder. The filler metal 36 may be formed while covering the region other than the conductive section 30 with a resist. A bump can be formed by the conductive section 30 or by the conductive section 30 and the filler metal 36 by these steps.

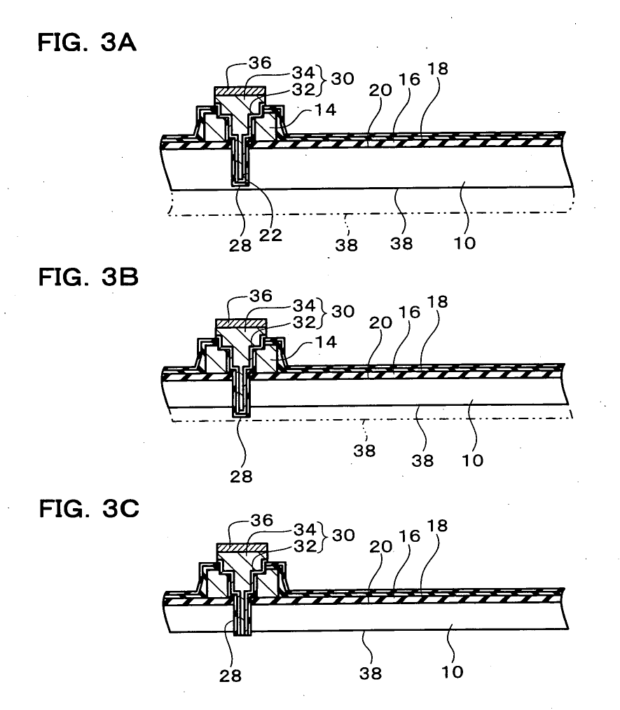

In the present embodiment, as shown in FIG. 3A, a second surface 38 (surface opposite to the first surface 20) of the semiconductor substrate 10 may be removed by using at least one of mechanical polishing/grinding and chemical polishing/grinding. This step is terminated before the insulating layer 28 formed in the depression 22 is exposed. A step shown in FIG. 3B may be performed without performing the step shown in FIG. 3A.

As shown in FIG. 3B, the conductive section 30 is caused to project from the second surface 38. For example, the second surface 38 of the semiconductor substrate 10 is etched so that the insulating layer 28 is exposed. In more detail, the second surface 38 of the semiconductor substrate 10 is etched so that the conductive section 30 projects in a state in which the conductive section 30 (section of the conductive section 30 inside the depression 22 in more detail) is covered with the insulating layer 28. The second surface 38 may be etched by using an etchant having properties which allow the amount of etching for the semiconductor substrate 10 (formed of Si, for example) to be greater than the amount of etching for the insulating layer 28 (formed of SiO₂, for example). The etchant may be SF₆, CF₄, or Cl₂ gas. Etching may be performed by using a dry etching system. The etchant may be a mixed solution of hydrofluoric acid and nitric acid or a mixed solution of hydrofluoric acid, nitric acid, and acetic acid.

As shown in FIG. 3C, the conductive section 30 is ground or polished until the fresh surface (surface formed only of a constituent material, that is, surface from which an oxide film and a deposited organic substance are removed) is exposed. A grindstone may be used for grinding. For example, a grindstone having a grit of about #100 to #4000 may be used. Use of a grindstone having a grit of about #1000 to #4000 prevents breakage of the insulating layer 28. Abrasive cloth may be used for polishing. The abrasive cloth may be a suede type or foamed urethane type abrasive cloth, or may be nonwoven fabric. Slurry in which colloidal silica as abrasive particles is dispersed in an alkaline cationic solution such as Na or NH₄ may be used for polishing. The abrasive particles may have a particle diameter of about 0.03 to 10 μm, and be dispersed at a percentage of about 10 wt %. The slurry may include an additive such as a chelating agent, ammonia, or a hydrogen peroxide aqueous solution. The abrasive pressure may be about 5 g/cm² to 1 kg/cm².

In the case where the insulating layer 28 is formed in the depression 22, the insulating layer 28 is polished or ground before polishing or grinding the conductive section 30. Polishing or grinding of the insulating layer 28 may be continuously performed with polishing or grinding of the conductive section 30. The insulating layer 28 is removed at least in the area formed on the bottom surface of the depression 22. After exposing the conductive section 30, the fresh surface of the conductive section 30 is exposed. The periphery of the end of the conductive section 30 may be covered with the insulating layer 28 while exposing the fresh surface of the conductive section 30. The fresh surface of the outer layer section 32 (barrier layer, for example) may be exposed so that the fresh surface of the center section 34 of the conductive section 30 is not exposed, or the fresh surfaces of the outer layer section 32 and the center section 34 may be exposed.

At least one of the steps shown in FIGS. 3A to 3C may be performed in a state in which a reinforcement material such as a glass plate, resin layer, or resin tape is provided (attached) to the first surface 20 of the semiconductor substrate 10 (using an adhesive or adhesive sheet), for example.

The conductive section 30 can be caused to project from the second surface 38 of the semiconductor substrate 10 by these steps. The projecting conductive section 30 becomes a bump electrode. The conductive section 30 also functions as a penetrating electrode formed from the first surface 20 to the second surface 38. According to the present embodiment, since the fresh surface of the conductive section 30 is exposed, a penetrating electrode excelling in electrical connection characteristics can be formed. The conductive section 30 may be electrically connected with another part before the fresh surface is oxidized (immediately after the fresh surface is exposed or as soon as possible after the fresh surface is exposed (within 24 hours, for example)). A semiconductor device (semiconductor substrate including penetrating electrodes) can be manufactured by the above steps. The structure of the semiconductor device may be derived from the above-described manufacturing method.

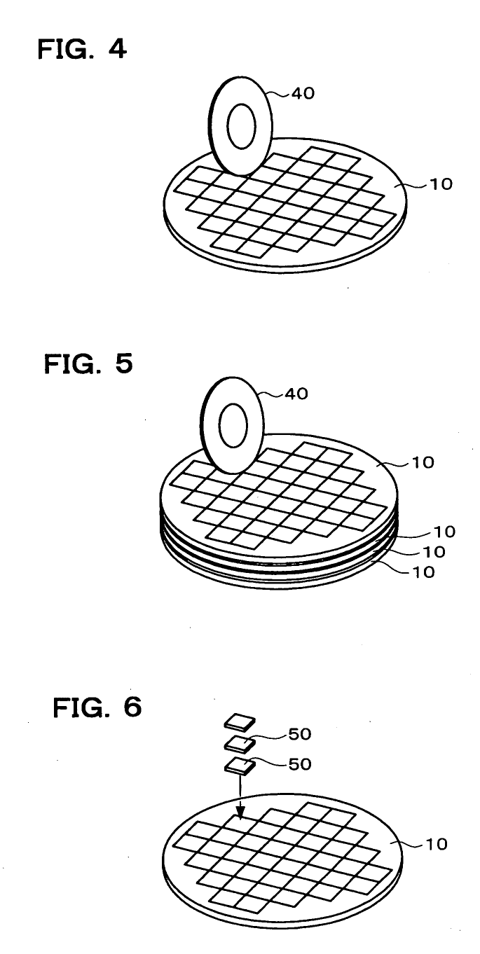

In the case where the semiconductor substrate 10 is a semiconductor wafer as shown in FIG. 4, the depression 22 may be formed corresponding to each of the integrated circuits 12 (see FIG. 1A), and the semiconductor substrate 10 may be cut (diced, for example). A cutter (dicer, for example) 40 or a laser (CO₂ laser or YAG laser, for example) may be used to cut the semiconductor wafer. This enables a semiconductor device (semiconductor chip including penetrating electrodes) to be manufactured. The structure of the semiconductor device may be derived from the above-described manufacturing method.

The method of manufacturing the semiconductor device may include stacking a plurality of the semiconductor substrates 10 including the conductive section 30, and electrically connecting the semiconductor substrates 10 through the conductive sections 30. In more detail, the conductive sections 30 may be electrically connected, or the conductive section 30 may be electrically connected with the electrode 14. A solder junction or a metal junction, an anisotropic conductive material (anisotropic conductive film or anisotropic conductive paste), pressure welding utilizing the shrinkage force of an insulating adhesive, or a combination of these may be used to provide electrical connection.

The semiconductor substrates 10 as semiconductor chips may be stacked. As shown in FIG. 5, the semiconductor substrates 10 as semiconductor wafers may be stacked. In this case, the stacked semiconductor substrates 10 may be cut. As shown in FIG. 6, the semiconductor chip 50 cut from the semiconductor substrate 10 may be stacked on the semiconductor substrate 10 as a semiconductor wafer. In this case, a plurality of the semiconductor chips 50 may be stacked.

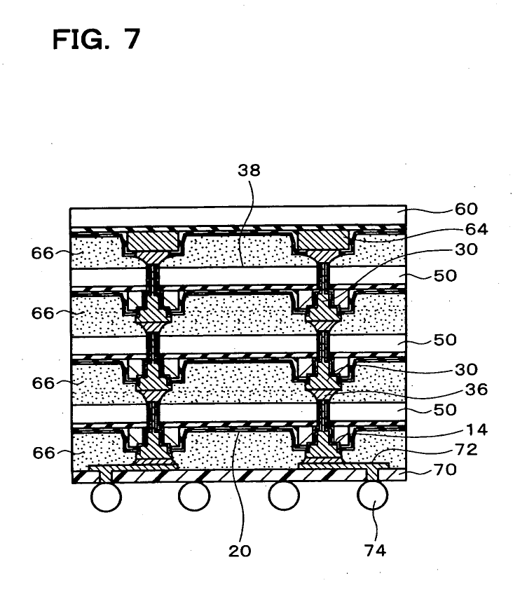

FIG. 7 is a view showing a semiconductor device (stacked-type semiconductor device) according to an embodiment of the present invention. The stacked-type semiconductor device includes a plurality of semiconductor chips 50 cut from the semiconductor substrate 10. The semiconductor chips 50 are stacked. The conductive sections 30 or the conductive section 30 and the electrode 14 may be bonded through the filler metal 36. A semiconductor chip 60 which does not include a penetrating electrode may be stacked on one of the stacked semiconductor chips 50 (outermost semiconductor chip 50 in the direction of the second surface 38, for example). The description of the semiconductor chip 50 applies to the semiconductor chip 60 except that the semiconductor chip 60 does not include a penetrating electrode. The conductive section 30 of the semiconductor chip 50 may be bonded to an electrode 64 of the semiconductor chip 60.

An insulating material 66 (adhesive, resin, or underfill material, for example) may be provided between the semiconductor chips 50 or the semiconductor chips 60 and 50. The bonding state of the conductive section 30 is maintained or reinforced by the insulating material 66.

The stacked semiconductor chips 50 may be mounted on an interconnect substrate 70. The outermost semiconductor chip 50 among the stacked semiconductor chips 50 may be mounted on the interconnect substrate 70 (interposer, for example). The semiconductor chip 50 may be mounted on the interconnect substrate 70 by face down bonding. In this case, the semiconductor chip 50 having the outermost (lowermost, for example) conductive section 30 in the direction of the first surface 20 is mounted on the interconnect substrate 70. For example, the projecting section of the conductive section 30 which projects from the first surface 20 or the electrode 14 may be electrically connected with (bonded to, for example) an interconnect pattern 72. The insulating material 66 (adhesive, resin, or underfill material, for example) may be provided between the semiconductor chip 50 and the interconnect substrate 70. The bonding state of the conductive section 30 or the electrode 14 is maintained or reinforced by the insulating material 66.

The stacked semiconductor chips 50 may be bonded face up to the interconnect substrate 70 (not shown). In this case, the projecting section of the conductive section 30 which projects from the second surface 38 is electrically connected with (bonded to, for example) the interconnect pattern 72. External terminals 74 (solder balls, for example) electrically connected with the interconnect pattern 72 are formed on the interconnect substrate 70. A stress relief layer may be formed on the semiconductor chip 50, an interconnect pattern may be formed on the stress relief layer from the electrode 14, and an external terminal may be formed on the interconnect pattern. Other details may be derived from the above manufacturing method.

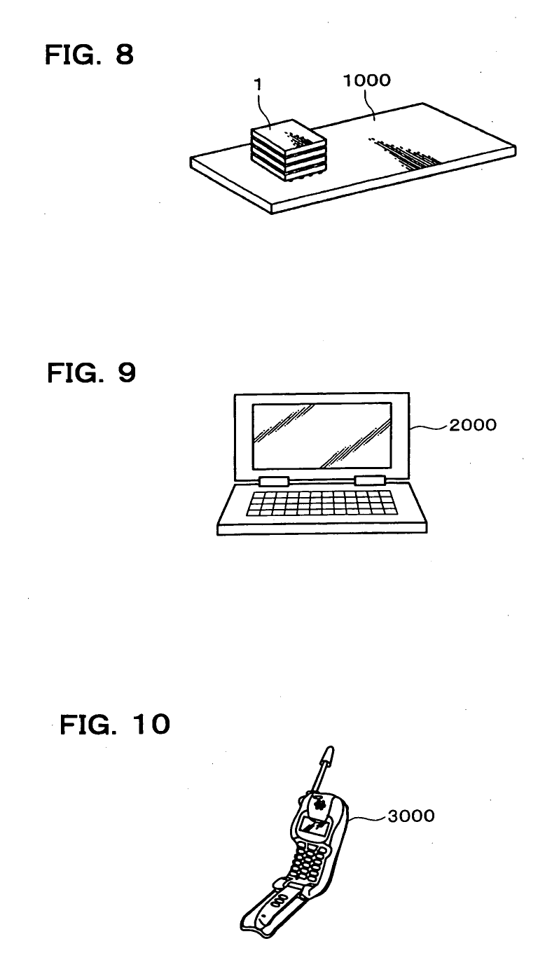

FIG. 8 shows a circuit board 1000 on which a semiconductor device 1, in which a plurality of semiconductor chips are stacked, is mounted. The semiconductor chips are electrically connected through the conductive sections 30. FIGS. 9 and 10 respectively show a notebook-type personal computer 2000 and a portable telephone 3000 as examples of electronic instruments including the above semiconductor device.

The present invention is not limited to the above-described embodiments. Various modifications and variations are possible. For example, the present invention includes configurations essentially the same as the configurations described in the embodiments (for example, configurations having the same function, method, and results, or configurations having the same object and results). The present invention includes configurations in which any unessential part of the configuration described in the embodiments is replaced. The present invention includes configurations having the same effects or achieving the same object as the configurations described in the embodiments. The present invention includes configurations in which conventional technology is added to the configurations described in the embodiments.

What is claimed is:

1. A method of manufacturing a semiconductor device comprising:
(a) forming a depression in a semiconductor substrate from a first surface of the semiconductor substrate, an integrated circuit being formed in the semiconductor substrate;
(b) forming a conductive section in the depression;
(c) causing the conductive section to project from a second surface of the semiconductor substrate, the second surface being opposite to the first surface; and
(d) grinding or polishing the conductive section until a fresh surface of the conductive section is exposed.

2. The method of manufacturing a semiconductor device as defined in claim 1, further comprising:
forming an insulating layer on a bottom surface and an inner wall surface of the depression after the step (a) and before the step (b),
wherein the conductive section is formed inside the insulating layer in the step (b).

3. The method of manufacturing a semiconductor device as defined in claim 2,
wherein the conductive section is caused to project in the step (c) in a state in which the conductive section is covered with the insulating layer, and
wherein the insulating layer and the conductive section are ground or polished in the step (d).

4. The method of manufacturing a semiconductor device as defined in claim 3,
wherein the conductive section is caused to project from the second surface of the semiconductor substrate in the step (c) by etching the second surface using an etchant having properties which cause the amount of etching to the semiconductor substrate to be greater than the amount of etching to the insulating layer.

5. The method of manufacturing a semiconductor device as defined in claim 1,
wherein the semiconductor substrate is a semiconductor wafer in which a plurality of the integrated circuits are formed, and the depression is formed corresponding to each of the integrated circuits, and
wherein the method further comprises cutting the semiconductor substrate.

6. The method of manufacturing a semiconductor device as defined in claim 1, further comprising:
stacking a plurality of the semiconductor substrates which has been subjected to the steps (a) to (d), and electrically connecting the semiconductor substrates through a plurality of the conductive sections.

7. The method of manufacturing a semiconductor device as defined in claim 2, further comprising:
stacking a plurality of the semiconductor substrates which has been subjected to the steps (a) to (d), and electrically connecting the semiconductor substrates through a plurality of the conductive sections.

8. The method of manufacturing a semiconductor device as defined in claim 3, further comprising:
stacking a plurality of the semiconductor substrates which has been subjected to the steps (a) to (d), and electrically connecting the semiconductor substrates through a plurality of the conductive sections.

9. The method of manufacturing a semiconductor device as defined in claim 4, further comprising:
stacking a plurality of the semiconductor substrates which has been subjected to the steps (a) to (d), and electrically connecting the semiconductor substrates through a plurality of the conductive sections.

10. The method of manufacturing a semiconductor device as defined in claim 1, further comprising:
stacking a plurality of the semiconductor substrates which has been subjected to the steps (a) to (d), and electrically connecting the semiconductor substrates through a plurality of the conductive sections.

11. A semiconductor device manufactured by the method as defined in claim 1.

12. A semiconductor device manufactured by the method as defined in claim 6.

13. A circuit board on which the semiconductor device as defined in claim 11 is mounted.

14. A circuit board on which the semiconductor device as defined in claim 12 is mounted.

15. An electronic instrument comprising the semiconductor device as defined in claim 11.

16. An electronic instrument comprising the semiconductor device as defined in claim 12.
